(19) United States
(12) Patent Application Publication
(10) Pub. No.: US 2007/0084499 A1
(43) Pub. Date: Apr. 19, 2007

(54) Thermoelectric device produced by quantum confinement in nanostructures

(76) Inventor: Biprodas Dutta, Silver Spring, MD (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(21) Appl. No.: 11/250,606

(22) Filed: Oct. 14, 2005

(51) Int. Cl. H01L 35/02

(52) U.S. Cl. 136/230

(57) ABSTRACT

The present invention provides a thermoelectric device comprising a film of thermoelectric material deposited on a substrate, and one or more electrodes located within the thermoelectric film, wherein the thermoelectric film is partially oxidized to form an oxide layer, which is melted to form an electrical insulating and protective barrier on a top surface of the film.

### FIELD OF THE INVENTION

The present invention is directed to thermoelectric devices and more particularly to thermoelectric devices produced by utilizing the concepts of quantum confinement in thin films.

### BACKGROUND OF THE INVENTION

Thermoelectric materials generate electricity when subjected to a thermal gradient and produce a thermal gradient when electric current is passed through them. Scientists have been trying to harness practical thermoelectricity for decades because practical thermoelectricity could, inter alia: (1) replace fluorocarbons used in existing cooling systems such as refrigerators and air conditioners; and (2) reduce harmful emissions during thermal power generation by converting some or most of the waste heat into electricity. However, the promise of practical thermoelectricity has not yet been fulfilled. One problem is that, because of its low efficiency, the industry standard in thermoelectric technology cannot be functionally integrated into everyday heating and cooling products and systems.

Bulk form thermoelectric devices such as thermoelectric generators (TEG), thermoelectric refrigerators (TER) and thermoelectric heat pumps are used for the direct conversion of heat into electricity, or for the direct conversion of electricity into heat. However, the efficiency of energy conversion and/or coefficient of performance of these bulk form thermoelectric devices are considerably lower than those of conventional reciprocating or rotary heat engines and vapor- compression systems. In view of these drawbacks and the general immaturity of the technology, bulk form thermoelectric devices have not attained immense popularity.

Early thermoelectric junctions were fashioned from two different metals or alloys capable of producing a small current when subjected to a thermal gradient. A differential voltage is created as heat is carried across the junction, thereby converting a portion of the heat into electricity. Several junctions can be connected in series to provide greater voltages, connected in parallel to provide increased current, or both. Modern thermoelectric generators can include numerous junctions in series, resulting in higher voltages. Such thermoelectric generators can be manufactured in modular form to provide for parallel connectivity to increase the amount of generated current.

In 1821, Thomas Johann Seebeck discovered the first thermoelectric effect, referred to as the Seebeck effect. Seebeck discovered that a compass needle is deflected when placed near a closed loop made of two dissimilar metals, when one of the two junctions is kept at a higher temperature than the other. This established that a voltage difference is generated when there is a temperature difference between the two junctions, wherein the voltage difference is dependent on the nature of the metals involved. The voltage (or EMF) generated per °C. thermal gradient is known as Seebeck coefficient.

In 1833, Peltier discovered the second thermoelectric effect, known as the Peltier effect. Peltier found that temperature changes occur at a junction of dissimilar metals, whenever an electrical current is caused to flow through the junction. Heat is either absorbed or released at a junction depending on the direction of the current flow.

Sir William Thomson, later known as Lord Kelvin, discovered a third thermoelectric effect called the Thomson effect, which relates to the heating or cooling of a single homogeneous current-carrying conductor subjected to a temperature gradient. Lord Kelvin also established four equations (the Kelvin relations) correlating the Seebeck, Peltier and Thomson coefficients. In 1911, Altenkirch suggested using the principles of thermoelectricity for the direct conversion of heat into electricity, or vice versa. He created a theory of thermoelectricity for power generation and cooling, wherein the Seebeck coefficient (thermo-power) was required to be as high as possible for best performance. The theory also required that the electrical conductivity to be as high as possible, coupled with a minimal thermal conductivity.

Altenkirch established a criterion to determine the thermopower conversion efficiency of a material, which he named the power factor (PF). The latter is represented by the equation: PF=S²*σ=S²/ρ, where S is the Seebeck coefficient or thermo-power, σ is the electrical conductivity and ρ (1/σ) is the electrical resistivity. Altenkirch was thereby led to establish the equation: Z =S²*σ/k=S²/ρ*k=PF/k, wherein Z is the thermoelectric figure of merit having the dimensions of K⁻¹. The equation can be rendered dimensionless by multiplying it by the absolute temperature, T, at which the measurements for S, ρ and k are conducted such that the dimensionless thermoelectric figure of merit or ZT factor equals (S²*σ/k)T. It follows that to improve the performance of a thermoelectric device the power factor should be increased as much as possible, whereas k (thermal conductivity) should be decreased as much as possible.

The ZT factor of a material indicates its thermopower conversion efficiency. Forty years ago, the best ZT factor in existence was about 0.6. After four decades of research, commercially available systems are still limited to ZT values that barely approach 1. It is widely recognized that a ZT factor greater than 1 would open the door for thermoelectric power generation to begin supplanting existing power-generating technologies, traditional home refrigerators, air conditioners, and more. Indeed, a practical thermoelectric technology with a ZT factor of even 2.0 or more will likely lead to the production of the next generation of heating and cooling systems. In view of the above, there exists a need for a method for producing practical thermoelectric technology that achieves an increased ZT factor of around 2.0 or more.

Solid-state thermoelectric coolers and thermoelectric generators in nano-structures have recently been shown to be capable of enhanced thermoelectric performance over that of corresponding thermoelectric devices in bulk form. It has been demonstrated that when certain thermoelectrically active materials (such as PbTe, Bi₂Te₃ and SiGe) are reduced in size to the nanometer scale (typically about 4-100 nm), the ZT factor increases dramatically. This increase in ZT has raised expectations of utilizing quantum confinement for developing practical thermoelectric generators and coolers [refrigerators]. A variety of promising approaches such as transport and confinement in nanowires and quantum dots, reduction of thermal conductivity in the direction perpendicular to superlattice planes, and optimization of ternary or quaternary chalcogenides and skutterudites have been investigated recently. However, these approaches are cost-prohibitive and many of the materials cannot be manufactured in significant amounts.

In view of the above, there exists a need for a method for generating practical thermoelectric devices from nanostructures that possess significantly larger ZT factors as compared to those of thermoelectrically active materials in bulk form.

There also exists a need for a method for mass-producing practical thermoelectric devices at a ZT factor of at least 2.0.

There further exists a need for a method for producing practical thermoelectric devices that may be cost-effectively integrated into everyday heating and cooling products.

There also exists a need for a method for producing practical thermoelectric devices that provide a smaller footprint than the industry standard.

There further exists a need for a method for producing practical thermoelectric devices capable of being mass-produced at a lower cost than the current industry standard.

In addition, there exists a need for a method for generating electric power from thermoelectric generators to utilize waste heat (e.g., industrial, domestic, automobile, etc.).

### SUMMARY OF THE INVENTION

In view of the foregoing, it is an object of the present invention to provide a method for generating practical thermoelectric devices from nanostructures that possess significantly larger ZT factors as compared to those of thermoelectrically active materials in bulk form.

It is an additional object of the present invention to provide a method for mass-producing practical thermoelectric devices at a ZT factor of at least 2.0.

It is another object of the present invention to provide a method for producing practical thermoelectric devices that may be cost-effectively integrated into everyday heating and cooling products.

Additionally, it is an object of the present invention to provide a method for producing practical thermoelectric devices that provide a smaller footprint than the industry standard.

It is a further object of the present invention to provide a method for producing practical thermoelectric devices capable of being mass-produced at a lower cost than the current industry standard.

It is yet another object of the present invention to provide a method for generating electric power from thermoelectric generators to utilize waste heat (e.g., industrial, domestic, automobile, etc.).

The preferred method of the present invention for preparing a thermoelectric device comprises the steps of selecting glass or any other substrate having suitable electrically insulating and thermally resistive properties, depositing a film of thermoelectric material on the substrate, applying one or more electrodes within the thermoelectric film and oxidizing the thermoelectric film to form an oxide layer (e.g., PbO—TeO₂) on the top surface of the film. For example, the substrate may comprise KCl, whereas the thermoelectric material may comprise PbTe. The thermoelectric film is vapor deposited on the glass substrate using a conventional vapor deposition system at a vacuum of about 10⁻⁶ torr to about 10⁻⁷ torr.

For example, in the case of PbTe as the preferred thermoelectric material, the optimum thickness of the deposited film is approximately 50-100 nm. In particular, the initial film thickness is ˜200 nm. However, the substrate with the deposited PbTe film is then subjected to oxidation such that the top ˜100 nm of the film is converted to a layer having a composition approximating PbO—TeO₂. Subsequently, the topmost oxidized layer is subjected to flash heating for a brief time period when the oxide layer is melted and converted into a glass.

The glass layer has been determined to be an effective insulator while the layer of PbTe underneath the oxide layer retains its high electrical conductivity and high Seebeck coefficient. The substrate may be chosen from a wide variety of insulating materials such as but not limited to potassium chloride (KCl), silicon, quartz, pyrex, mica, or a PbO₂—TeO₂ glass containing certain other ingredients such as but not limited to silicon dioxide, aluminum oxide, calcium oxide, and boron oxide. The thermoelectric film is vapor deposited on the substrate using a conventional vapor deposition system at a vacuum of about 10⁻⁷ to 10⁻⁹ torr. Alternatively, the thermoelectric film can be vapor deposited on the substrate under a flow of inert gas, such as argon, at considerably higher pressures (e.g., 10⁻² torr).

The preferred method for preparing the thermoelectric device may further comprise the step of flash heating the substrate to melt the oxide layer to convert the oxide layer from a relatively porous material into a relatively dense glassy material. The thickness of the thermoelectric film decreases with increased oxidation time, whereas the thickness of the oxide layer of PbO—TeO₂ increases with increased oxidation time. The method steps may be repeated to produce a thermoelectric device having multiple thermoelectric film layers separated by insulating layers. According to the preferred embodiment, multiple thermoelectric devices of the present invention may be employed in a refrigerator, generator or Peltier device. The thermoelectric film preferably is less than 300 nm in thickness, more preferably between 50 nm and 200 nm in thickness, and most preferably between 75 nm and 100 nm in thickness. The electrodes can be formed from any material that will not melt or oxidize under the operating temperature environment to which the device is exposed. Consequently, the electrodes preferably comprise a material such as platinum, gold or silver for maximum robustness.

A further aspect of the invention involves a method for preparing a thermoelectric device, comprising depositing a film of thermoelectric material on a substrate, locating one or more electrodes within the thermoelectric film, partially oxidizing the thermoelectric film to form an oxide layer and melting the oxide layer to form an insulating and protective barrier on a top surface of the film.

Another aspect of the invention involves a method for preparing a thermoelectric device, comprising depositing a thermoelectric film of PbTe on a substrate, treating the thermoelectric film to form an oxide layer comprising PbO—TeO₂ and treating the oxide layer to form an insulating and protective barrier on a top surface of the film.

A further aspect of the invention involves a method for preparing a thermoelectric device, comprising depositing a thermoelectric film on a substrate, treating the thermoelectric film to form an oxide layer and treating the oxide layer to form an insulating and protective barrier on a top surface of the film.

An additional aspect of the invention involves a thermoelectric device, comprising a substrate, a thermoelectric layer and a barrier layer, wherein the barrier layer is formed by partially oxidizing the thermoelectric film to form an oxide layer, and the oxide layer is melted form the barrier layer. The substrate forms an insulating and protective barrier on a bottom top surface of the thermoelectric layer, while the barrier layer forms an insulating and protective barrier on a top surface of the thermoelectric layer. The thermoelectric layer preferably comprises a film of thermoelectric material that is deposited on the substrate. Suitable thermoelectric materials include but are not limited to PbTe, Bi₂Te₃, SiGe, and ZnSb. Further examples include but are not limited to compounds composed primarily of elements from Groups IV, V, and VI of the period table, with or without the inclusion of Zn or Cd or both Zn and Cd. Suitable substrate materials include but are not limited to KCl, KBr, Si, quartz glass, quartz crystal, mica, or Pyrex glass.

Another aspect of the invention involves a thermoelectric device, comprising a substrate, a thermoelectric film comprising PbTe and a barrier layer comprising PbO—TeO₂. The thermoelectric device may further comprise additional alternating layers of thermoelectric material and barrier material.

A further aspect of the invention involves replacement of the oxidation step, which involves treatment with oxygen to produce an oxide layer, by a sulfidation or a nitridation step. The sulfidation step, which involves treatment with sulfur-containing compounds, produces a sulfide layer which can be converted by heat treatment to a chalcogenide glass that performs a similar function as the oxide layer. Similarly, the nitridation step, which involves treatment with nitrogen-containing compounds, produces a nitride layer which can be converted by heat treatment to a nitride glass that performs a similar function as the oxide layer.

### BRIEF DESCRIPTION OF THE DRAWINGS

FIGS. 1A and 1B illustrate top and side views, respectfully, of a preferred thermoelectric film layer of the invention having electrodes embedded therein;

FIG. 2 is a table depicting measurements for thermoelectric power (S), electrical conductivity (σ) and S² σ for thermoelectric film samples prepared on a PbO—TeO₂—B₂O₃ substrate at various thicknesses;

FIG. 3 is a graphical representation of S² σ plotted against sample thickness for the data of FIG. 2;

FIG. 4 is a table depicting measurements for thermoelectric power (S), electrical conductivity (σ) and S² σ for thermoelectric film samples prepared on a KCl substrate at various thicknesses;

FIG. 5 is a graphical representation of S² σ plotted against sample thickness for the data of FIG. 4; and

FIG. 6 illustrates a preferred method of preparing a preferred thermoelectric device in accordance with the principles of the present invention.

### DETAILED DESCRIPTION

In the following paragraphs, the present invention will be described in detail by way of example with reference to the attached drawings. Throughout this description, the preferred embodiment and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

Before starting a description of the Figures, some terms will now be defined.

Bulk Material: Macroscopic-sized thermoelectric materials that are typically larger than 1 micron or 1 micrometer in all three dimensions.

Chalcogenides: Group VI elements of the periodic table.

Chemical Vapor Deposition: Deposition of thin films (usually dielectrics/insulators) on wafer substrates by placing the wafers in a mixture of gases, which react at the surface of the wafers. This can be done at medium to high temperature in a furnace, or in a reactor in which the wafers are heated but the walls of the reactor are not. Plasma enhanced chemical vapor deposition avoids the need for a high temperature by exciting the reactant gases into a plasma.

Doping: Deliberately adding a very small amount of foreign substance to an otherwise very pure semiconductor crystal. These added impurities give the semiconductor an excess of conducting electrons or an excess of conducting holes (the absence of conducting electrons).

Efficiency: Efficiency is the power generated by a system divided by the power fed into it, a measure of how well a material converts one form of energy into another. Efficiency stands at a mere 8 to 12% for bulk form thermoelectric devices that are currently available or on the near horizon.

Figure of Merit: The thermoelectric figure of merit, ZT, is given by ZT =(S²*σ/k)*T, where S is the Seebeck coefficient, T is the absolute temperature, a is the electrical resistivity, and k is the thermal conductivity.

Lead Telluride: PbTe is one of the most commonly used thermoelectric material other than Bi₂Te₃. PbTe.is typically used for power generation because this material exhibits its highest ZT at temperatures between 400 and 500° C. and has an effective operating range of about 200° C. around 500° C.

Nano: A prefix meaning one-billionth, or 0.000000001. For example, the wavelength of the ultraviolet light used to etch silicon chips is a few hundred nanometers. The symbol for nanometer is nm.

Quantum Confinement: Quantum Confinement takes place when carriers of electricity (electrons or holes) are confined in space by reducing the size of the conductor. For example, a very thin conducting film reduces the freedom of a carrier by limiting its freedom to propagate in a direction perpendicular to the plane of the film. The film is said to be a 2-d structure and the carrier in such a film is said to be quantum confined in one direction. It can move around in two other directions, i.e., in the plane of the film.

Seebeck Coefficient: The electromotive force generated in a material when it is subjected to a thermal gradient and is normally expressed as microvolts per Kelvin. The thermoelectric power, or Seebeck coefficient, of a material has a large role in determining its ZT factor.

Thermal Conductivity: Thermal conductivity is an inherent property of a material that specifies the amount of heat transferred through a material of unit cross-section and unit thickness for unit temperature gradient. Though thermal conductivity is an intrinsic property of a medium, it depends on the measurement temperature. The thermal conductivity of air is about 50% greater than that of water vapor, whereas the thermal conductivity of liquid water is about 25 times that of air. Thermal conductivities of solids, especially metals, are thousands of times greater than that of air.

The present invention is directed to a method for producing practical thermoelectricity by developing quantum-confined structures capable of exhibiting high ZT values. As explained hereinabove, the equation for the thermoelectric figure of merit, Z, can be rendered dimensionless by multiplying it by an absolute temperature, T, such as the temperature of the hot junction of the thermoelectric device. It follows that the dimensionless thermoelectric figure of merit, ZT=(S²*σ/k)*T, can be used in the evaluation of the performance and energy conversion efficiency, of any thermoelectric material or device.

For films of PbTe, if the bulk thermal conductivity (k) of PbTe is considered, the ZT factor at 750 K is still very high (i.e., ZT of around 2.0 or more) using ZT=(S²*σ/k)*T. ZT factors increase with temperatures between about 300 K and 750 K. For PbTe-based thermoelectric devices, the value of S²*σ tends to peak at a certain level with the ZT factors increasing with decreasing film thickness. However, after a certain film thickness is reached, ZT factors begin to fall with decreasing film thickness.

According to the principles of the invention, a thermoelectric device exhibiting a high ZT factor is produced by controlled oxidation. All of the testing data provided herein were collected using electrical/Seebeck measurements, along with testing of thermal properties as a function of heat-treatment and atmosphere. When the data were plotted on a ZT vs. treatment time and temperature plot, a maximum in ZT of around 2.0 was observed under certain experiment conditions. These thermoelectric device structures may be employed in thermoelectric applications such as thermoelectric generators (TEG's). The same principles may be applied to make films of thermoelectric coolers from materials exhibiting quantum confined Peltier effect such as Bi₂Te₃. Known thermoelectric materials include superlattices, quantum wells, nanowires, and quantum dots.

Thin films of PbTe can be tailored to exhibit n-type or p-type conduction quite easily, either by changing the stoichiometry of Pb and Te or by adding some minor components/impurities. According to the principles of the invention, PbTe may be deposited onto various substrates. Additionally, PbO—TeO₂ has been observed to form excellent glasses without substantially crystallizing if certain minor additives are included. Such glasses may be employed as substrates or substrate layers.

During testing, PbTe films (e.g., initially >150 nm) were deposited on a suitable substrate. After a barrier coating was applied to the film, it was covered with a suitable glass/crystal. Alternatively, the PbTe film was deposited without a barrier layer, and then the sample was quickly removed from the vapor-deposition chamber, covered with a suitable glass substrate and immediately put back under vacuum. The composite was subsequently heated to form a device, which was treated under various pressures, temperatures and time conditions. An oxide/glassy interface was then induced to grow into the thick film in a controlled manner. At certain treatment conditions, abnormally high thermopower and electrical conductivity were detected.

According to the principles of the invention, there exist a plurality of phases for producing a two dimensional thermoelectric device, the phases including: (1) raw material; (2) substrate preparation; (3) surface preparation and cleaning; (4) barrier layer deposition; (5) application of electrodes; (6) deposition of thermoelectrically active material; (7) deposition of multiple layers; (8) connection of layers into a circuit; and (9) encapsulation of multiple devices into a module. The selection of preferred raw materials involves the selection of appropriate thermoelectric materials as well as the selection of appropriate insulation and barrier materials.

Turning now to substrate preparation, the insulation substrate surface should be made as smooth, even and flat as possible. In other words, there should be minimal undulation on the substrate surface in order to properly apply the thermoelectric material onto the surface. Nano-surface smoothing may be required in order to achieve atomic-level accuracy. Additionally, no excess chemicals or dust should reside on the substrate surface since any foreign particles residing on critical surfaces may hinder the performance. For these reasons, all critical surfaces should be thoroughly cleaned and prepared before use.

In accordance with an aspect of the invention, a barrier layer is a thin veneer or film of a chemical disposed between insulating and thermoelectric layers. The purpose of the barrier layer is to prevent oxygen from interacting with the thermoelectric material, thereby impairing the thermoelectric performance of the thermoelectric material. A plurality of electrodes are placed on the substrate prior to vapor deposition of the thermoelectric layer such that the electrodes are embedded within the thermoelectric layer. The electrode contacts preferably comprise a material that will not melt or oxidize under high temperature environments. By way of example, the electrode contacts may comprise platinum, gold, silver or other suitable materials.

In accordance with the principles of the invention, a thermoelectric device is created by applying alternate layers of barrier material and thermoelectric material to a substrate. A preferred thermoelectric device of the present invention comprises a substrate, a thermoelectric layer, and a barrier layer, wherein the substrate and barrier layer comprise insulating layers for the thermoelectric material. A thermoelectric device having multiple thermoelectric layers is produced by adding any number of continuous depositions of alternating layers of thermoelectric and barrier materials to the substrate. The electrodes from each thermoelectric layer are connected together with an electrically conducting material that creates a circuit. There exist many other known methods of connecting electrodes to create a circuit (e.g., hard wiring), and such methods are understood to be within the scope of the invention. An alternative thermoelectric device of the present invention comprises a first barrier layer, a thermoelectric layer, and a second barrier layer, which may be followed by any number of continuous depositions of alternating layers of thermoelectric and barrier materials.

Numerous thermoelectric materials, including PbTe, are sensitive to oxygen, which can degrade thermoelectric performance. For this reason, such thermoelectric materials must be sealed off and protected from oxygen contamination within the target environment range. Of course, a thermoelectric device is not commercially viable if it cannot withstand the elements and environment it is intended to function under. In order to choose the preferred materials for the thermoelectric thin film structures of the present invention, the electrical conductivity and thermopower of thin films on various substrate materials including different glasses, were studied.

During testing, a low vacuum vapor deposition system is employed to deposit thermoelectric films in low vacuum of around 10⁻² torr. The vapor deposition system may comprise a ceramic or glass tube that is heated at different portions along its length by electric coils wrapped around the outside of the tube. Proper thermal insulation is provided around the coils to reduce heat loss from the heating elements directly to the atmosphere. Suitable materials for the tube include, but are not limited to, mullite, alumina and quartz. One end of the tube is connected to a vacuum pump while the other end is connected to a manifold providing a continuous flow of gas inside the tube. According to an alternative embodiment of the invention, vapor deposition may be performed at a higher vacuum of about 10⁻⁷ to 10⁻⁹ torr or greater, for example using a conventional bell-jar.

Thermoelectric materials such as PbTe, Bi₂Te₃, SiGe, and ZnSb, in the form of granules or powder, may be placed on a boat made of a high melting material such as tungsten. The tungsten boat is placed at an appropriate location inside the tube where the temperature may be raised to the melting temperature of the thermoelectric material or higher. In addition, a second boat containing a substrate material is placed within an appropriate section of the vapor deposition tube, such that the substrate material is subjected to a desired temperature during or after the film is deposited. By way of example, the substrate material may comprise silicon wafers, quartz wafers, glass wafers, barium fluoride crystals and other suitable materials. A third boat containing a suitable barrier layer material such as barium fluoride (BaF₂) is also placed within an appropriate section of the vapor deposition tube.

In operation, a film of thermoelectric material having a predetermined thickness is vapor deposited on the substrate. Then, a barrier layer having a predetermined thickness is vapor deposited on the thermoelectric film such that the thermoelectric film does not come in contact with the ambient atmosphere. The thickness of the film may be monitored with a conventional quartz oscillator. Alternatively, the film thickness may be monitored by scanning electron microscopy after the film deposition is completed. Once determined, the deposition parameters resulting in a desired film thickness may be repeated to reproduce films of desired thicknesses.

Prior to vapor deposition, an Ar/H₂ gas mixture is introduced within the vapor deposition tube to remove traces of oxygen gas that may be adsorbed on the exposed surfaces of all fixtures and tube surfaces. The gas mixture may be applied for period of between about 1 minute to about 60 minutes or more. Alternatively, oxygen removal may be achieved by passing other inert gases, or mixtures of inert gases, through the system.

FIGS. 1A and 1B illustrate top and side views, respectively, of a preferred thermoelectric film layer 22 of the invention having electrodes 20 embedded therein. In particular, electrodes 20 may be deposited on the substrate before vapor deposition of thermoelectric film layer 22. The electrodes 20 preferably comprise silver electrodes that are either painted on the substrate in the form of silver paste or vapor deposited on the substrate. Alternatively, any other suitable electrode material may be selected and deposited using any number of conventional techniques without departing from the scope of the invention. After oxygen removal and electrode deposition, the vapor deposition system is prepared for the deposition of alternating thin films of thermoelectric materials (e.g., PbTe) and barrier materials (e.g., EuS). Other suitable thermoelectric materials include Bi₂Te₃, SiGe, Zn₄Sb₃, Zn₃2 and Cd0₈Sb₃.

Referring to FIG. 2a chart is provided showing the values of specific deposition parameters for achieving certain thicknesses of the thermoelectric layer of PbTe. In a particular example, vapor deposition is performed for about 10 minutes at a PbTe temperature of approximately 940° C. and a substrate temperature of approximately 270° C. to achieve a thickness of between about 200 nm to about 300 nm. Additionally, vapor deposition may be performed for about 15 minutes at a PbTe temperature of approximately 950° C. and a substrate temperature of approximately 290° C. to achieve a thickness of between about 400 nm to about 450 nm. The barrier layer is deposited after the deposition of the thermoelectric layer. After vapor deposition of the barrier layer, a thermal treatment may be employed to allow the thermoelectric and barrier films to attain a desired crystal structure. The need for a thermal treatment is dictated by the substrate temperature employed during the previous film deposition.

In a variation of the vapor deposition technique described hereinabove, a thick film of thermoelectric material (e.g., between 1 micrometer and 100 nanometers) is initially deposited on the substrate, and then the thermoelectric film is reduced to a desired thickness. For example, the excess film may be converted to an oxide by subjecting the deposited thick film to an appropriate oxygen atmosphere. A time-temperature-study of the thick films under various oxygen partial pressures gives a precise protocol of producing the desired film thickness of the thermoelectric material. Similarly, the oxide layer may be replaced by a sulfide layer or a nitride layer by replacing the oxidation step by treatment with sulfur-containing compounds or nitrogen-containing compounds.

In a PbTe system, the preferred barrier layer of the thermoelectric device comprises PbO—TeO₂, which may be produced upon oxidation of the PbTe film layer. In particular, the PbO—TeO₂ layer produced on oxidation is an electrical insulator that serves as an efficient barrier layer. Furthermore, the porosity of the oxidized layer can be reduced by subjecting the sample to a short exposure to a temperature of about 700° C. such that the oxidized layer melts. In the case of a PbTe layer, the layer is untouched because the latter has a high melting temperature of 924° C. An oxidation treatment, coupled with a flash-heating procedure described above leaves a thin film of thermoelectric material under an oxide layer, which acts as a protective barrier. For the PbTe system, when the active thermoelectric layer has a thickness of about 50-100 nm, quantum confinement sets in, thereby imparting a high ZT value of between about 1.5 to 2.5, depending on the quality of the device.

Other embodiments of the invention feature the use of EuS as the material for the barrier layer applied in high vacuum systems equipped with electron beam evaporation facility. Although EuS has suitable insulating properties and is undoubtedly effective as a barrier layer material, it is both difficult to work with and very expensive. Moreover, EuS has a relatively high melting point such that the heating of the barrier layer may adversely affect the functionality of the vapor deposition system.

The preferred substrate should be compatible with the formation of the thermoelectric film layer and should be electrically insulating with respect to the thermoelectric material that is used. Silicon (Si), gallium arsenide (GaAs) and potassium chloride (KCl) were tested as possible substrates for the vapor deposited PbTe film. In addition, substrates formed from glasses based on PbO and TeO₂ among other oxides, have also been tested. The glasses preferably melt readily in a crucible of suitable material such as SiO₂ or alumina. The preferred glasses are those which exhibit sufficient flow at approximately 900° C. Some of these glasses exhibit a marked propensity towards fiber formation, and are therefore suitable to draw thermoelectric fibers clad in glasses.

The thermoelectric and conduction properties of the thermoelectric films are measured as a function of film thickness, regardless of the type of substrate employed. Once thin films were produced using the methods described above, the electrical conductivity (σ) and thermoelectric power (S) were measured and the variation of the parameter, S²*σ, was determined. The parameter, S²*σ, is determined experimentally, multiplied by the measurement temperature (in K) and divided by the known thermal conductivity (k) to provide the ZT values of the nano-films produced by the present invention.

During testing, a 28 amp current was applied to the tungsten boat containing PbTe, which has a melting point of about 925° C. The PbTe evaporated and left a good shiny film on the glass substrate like a mirror. The electrical conductivity and Seebeck coefficient (thermopower) were measured by employing techniques well known to practitioners of the art of measurements on thin films.

Testing of the uncoated glass substrate using the Van der Pauw 4-probe instrument showed that the sample was very resistive such that the instrument did not measure any conductivity. Similarly, the measurement of thermopower using a conventional method (e.g. by employing the Seebeck coefficient determination system, marketed by MMR Technologies, Mountain View, Calif.) did not produce any result on account of the high resistivity of the uncoated samples. However, the electrical conductivity and thermoelectric power of substrates coated with thermoelectric thin films was readily measurable, indicating that the measured values of electrical conductivity and thermoelectric power are attributable to the deposited films.

Using the high vacuum technique, a PbTe sample that was prepared using a current of about 28 amps, and maintained for about 1.5 minutes, was measured to determine its thickness by scanning electron microscopy. The thickness of the PbTe sample was about 1.10 μm (or 1100 nm). Preferably, the system is cleaned and calibrated such that the thickness of the film is less than about 300 nm, more preferably between 50 nm and 200 nm, most preferably between 75 nm and 100 nm.

Additional films were prepared for several substrates using a reduced current of about 20 amps maintained for a reduce time period of less than 1.5 minutes. In particular: (1) Sample 1 was produced at a current of about 25 amps maintained for approximately 1.25 minutes; (2) Sample 2 was produced at a current of about 20 amps maintained for approximately 1.25 minutes; (3) Sample 3 was produced at a current of about 24 amps maintained for approximately 1 minute; (4) Sample 4 was produced at a current of about 24 amps maintained for approximately 50 seconds; (5) Sample 5 was produced at a current of about 24 amps maintained for approximately 40 seconds; (6) Sample 6 was produced at a current of about 24 amps maintained for approximately 35 seconds; and (7) Sample 7 was produced at a current of about 24 amps maintained for approximately 25 seconds.

The above-identified samples were then measured to determine their respective thicknesses. Specifically: (1) Sample 1 had a thickness of about 400 nm; (2) Sample 2 produced no film; (3) Sample 3 had a thickness of about 200 nm; (4) Sample 4 had a thickness of about 150 nm; (5) Sample 5 had a thickness of about 125 nm; (6) Sample 6 had a thickness of about 75 nm; and (7) Sample 7 had a thickness of about 50 nm. It was demonstrated that the time periods for application of the current may be varied to achieve intermediate film thickness values.

A method of determining whether reducing the thickness of the film affects the ZT factor, electrical conductivity (σ) or the thermoelectric power (S) of the film will now be described. Particularly, the method includes the steps of: (1) preparing films of varying thicknesses; (2) measuring the electrical conductivity of each film; (3) measuring the thermoelectric power of each film; (4) determining the ZT factor for each film using assumed values for thermal conductivity k (bulk values are assumed since thermal conductivity is difficult to measure along the plane of the film); and (5) determining whether a reduction in film thickness has any affect on ZT factor, electrical conductivity or thermoelectric power.

PbTe film samples of varying thicknesses were studied to compile the electrical conductivity (σ) and thermoelectric power (S) of each film at different temperatures. Specifically, films having thicknesses of 50 nm, 75 nm, 100 nm and 150 nm were tested at a temperature of 300 K. Though the films were tested using a glass substrate comprising a mixture of PbO, TeO₂ and B₂O₃, other glass compositions and crystalline substrates may also be used to the same effect.

The 50 nm film was tested at a temperature of 300 K, and yielded an average thermoelectric power of S=212 μm/K and an average electrical conductivity of σ=7.12×10⁴(Ω.m)⁻¹. It follows that for the 50 nm film, S²σ=0.0023 W/m²K. The 75 nm film was tested at a temperature of 300 K, and yielded an average thermoelectric power of S=221 μm/K and an average electrical conductivity of σ=4.72×10⁴(Ω.m)⁻¹. The value for S² σ for the 75 nm film was 0.0032 W/m²K.

The 100 nm film was tested at a temperature of 300 K, and yielded an average thermoelectric power of S=204 μm/K and an average electrical conductivity of σ=6.73×10⁴ (Ω.m)⁻¹. It follows that for the 100 nm film, S² σ=0.0028 W/m²K. The 150 nm film was tested at a temperature of 300 K, and yielded an average thermoelectric power of S=206 μm/K and an average electrical conductivity of σ=3.48×10⁴(Ω.m)⁻¹. The value for S²σ for the 150 nm film was 0.0015 W/m²K.

Additional PbTe film samples of varying thicknesses (50 nm, 75 nm, 100 nm, 150 nm) were prepared on KCl substrates at a temperature of 750 K. The 50 nm film was tested at a temperature of 300 K, and yielded an average thermoelectric power of S=325 μm/K and an average electrical conductivity of σ=3.20×10⁴(Ω.m)⁻¹. It follows that for the 50 nm film, S²σ=0.0034 W/m²K. The 75 nm film was tested at a temperature of 750 K, and yielded an average thermoelectric power of S=341 μm/K and an average electrical conductivity of a =3.53×10⁴(Ω.m)⁻¹. The value for S²σ for the 75 nm film was 0.0041 W/m²K.

The 100 nm film was tested at a temperature of 300 K, and yielded an average thermoelectric power of S=315 μm/K and an average electrical conductivity of σ=3.13×10⁴(Ω.m)⁻¹. It follows that for the 100 nm film, S²σ=0.0031 W/m²K. The 150 nm film was tested at a temperature of 750 K, and yielded an average thermoelectric power of S=265 μm/K and an average electrical conductivity of σ=2.92×10⁴(Ω.m)⁻¹. The value for S²σ for the 150 nm film was 0.0021 W/m²K.

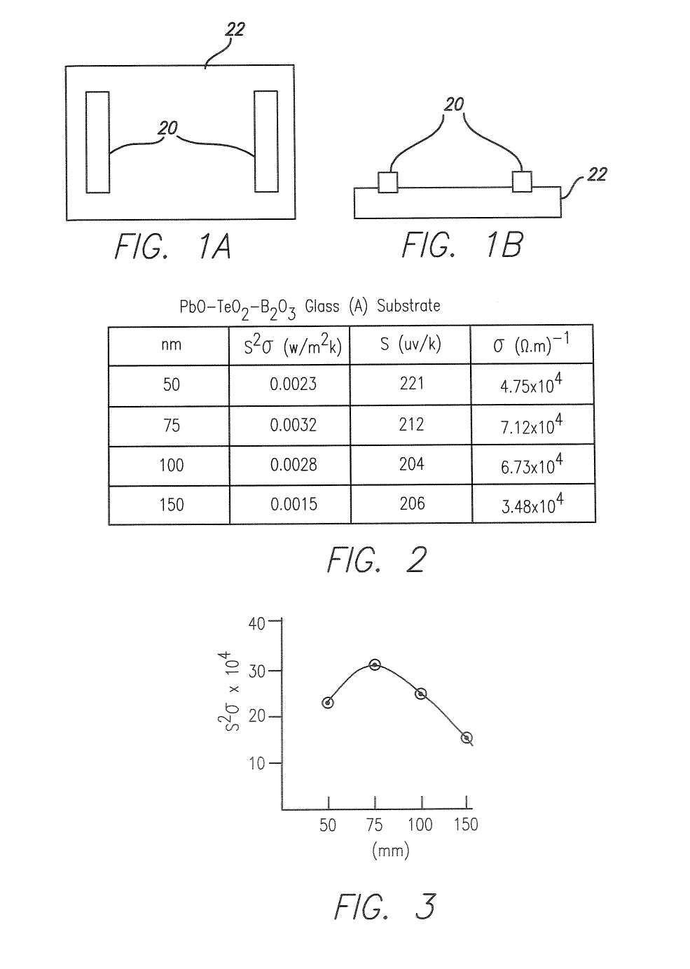

As set forth hereinabove, FIG. 2 is a table depicting measurements for thermoelectric power (S), electrical conductivity (σ) and S² σ for the PbTe samples prepared on a PbO—TeO₂—B₂O₃ substrate at thicknesses of 50 nm, 75 nm, 100 nm and 150 nm; while FIG. 3 is a graphical representation of S²σ plotted against sample thickness for the data of FIG. 2. As illustrated, the peak value for S²σ is observed at a thickness of between about 75 nm and about 80 mn.

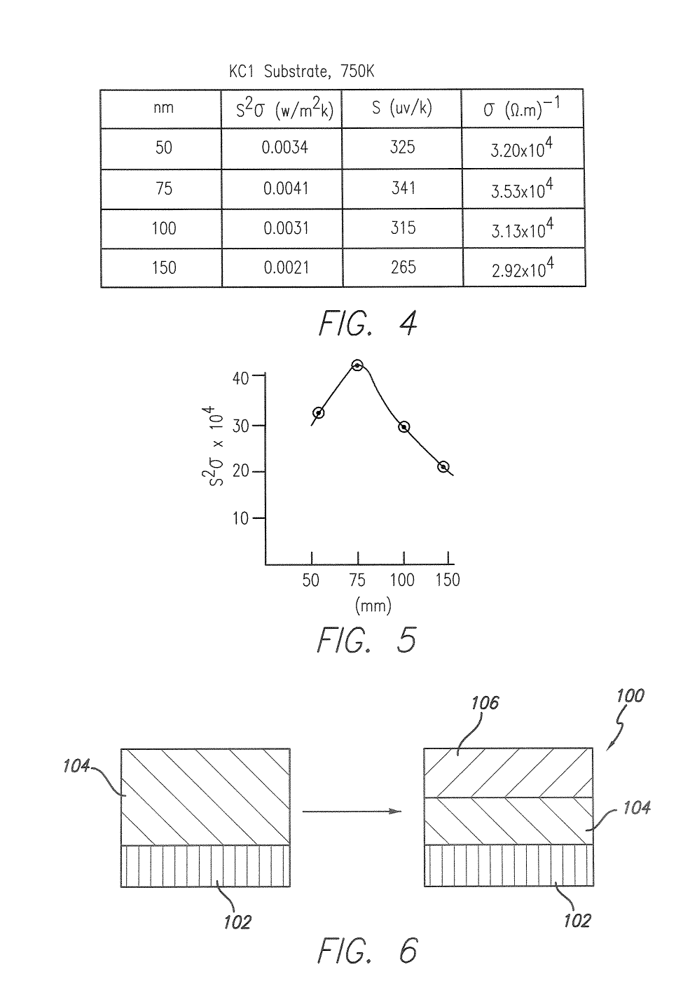

FIG. 4 is a table depicting measurements for thermoelectric power (S), electrical conductivity (σ) and S²σ for the PbTe samples prepared on a KCl substrate at thicknesses of 50 nm, 75 nm, 100 nm and 150 nm. FIG. 5 is a graphical representation of S²σ plotted against sample thickness for the data of FIG. 4. As depicted, the peak value for S²σ is again observed at a thickness of between about 75 nm and about 80 nm.

Using the known bulk thermal conductivity value for PbTe, the calculated ZT ((S ²σ/k)*T) factor at 750 K is >2.5. The S ²σ of PbTe exhibits a definite tendency to peak at a certain thickness value. Given that the best known ZT factors for bulk PbTe is around 0.5, the resultant ZT factors of around 2.0 or more is considered to be significantly enhanced by quantum confinement. FIGS. 3 and 5 clearly show a maximum ZT factor at a thickness of about 77 nm. The ZT factor increases with decreasing film thickness until this maximum value is reached, and then the ZT factor begins to decrease with further decrease in film thickness.

In accordance with the principles of the present invention, a method for preparing a thermoelectric device by controlled oxidation will now be described. The preferred thermoelectric material for the thermoelectric device is PbTe because of its advantageous thermoelectric properties and reasonable cost. A thermoelectric layer of PbTe having a thickness of approximately 50 nm to approximately 150 nm can be consistently reproduced. As would be appreciated by those of skill in the art, other thermoelectric materials having suitable thermoelectric properties (e.g., Bi₂Te₃) may be employed without departing from the scope of the invention.

Another aspect of the present invention involves the formation of a barrier layer by controlled oxidation of the thermoelectric film, wherein the formation of the barrier layer involves preparing a suitable glass for insulating the thermoelectric material. According to the preferred embodiment, a thick (approximately 1 micrometer) PbTe film is partially oxidized to form a relatively porous oxide (PbO—TeO₂) layer. Flash heating of this layer then converts it into an impervious glass. The PbO—TeO₂ glass melts at about 500° C. and the resultant glass layer provides appropriate electrical insulation of thin PbTe films. The thermoelectric device is formed by depositing alternating layers of thermoelectric material and insulating glass such that the thermoelectric layers are separated by insulating layers of glass.

Referring to FIG. 6, a preferred method for preparing a thermoelectric device 100 according to the principles of the present invention will now be described. Initially, a substrate 102 is chosen having suitable insulating and thermal properties. For example, substrate 102 may comprise a KCl, KBr, quartz or Si wafer, which may be purchased in a highly polished state. A glass having a surface finished to a high degree of polishing may also be used as the substrate to be placed within the vacuum chamber. Then, a film 104 of thermoelectric material, preferably PbTe, is deposited on the glass substrate 102. The next step involves partially oxidizing the thermoelectric film 104 to form an oxide layer 106.

After oxidation, a high vacuum is delivered and the O₂+Ar line is closed to about 700° C. The next step involves melting the oxide layer to form an electrical insulating and protective barrier on a top surface of the film. The step of melting the oxide layer 106 may comprise flash heating that is performed for approximately 30-45 seconds to convert the oxide layer 106 from a relatively porous glassy material into a relatively dense glassy material. The preferred method may also involve locating one or more electrodes within the thermoelectric film 104. As described hereinabove, PbO—TeO₂ may also be used (instead of KCl) as the glass substrate 102, as long as the heating of the oxide layer 106 is done from the top rather than using a bottom embedded heater. Similarly, the oxide layer may be replaced by a sulfide layer or a nitride layer by replacing the oxidation step by treatment with sulfur-containing compounds or nitrogen-containing compounds.

The preferred method for producing a thermoelectric device of the present invention may be automated to prepare hundreds (or even thousands) of layers, one on top of the other, and separated by insulating glass layers. The ZT factor of the resulting thermoelectric device preferably is around 2.0 or greater. Additionally, huge areas such as square meters or greater can be coated and oxidized repeatedly to form mega-device structures that are cut and cost-effectively integrated into everyday heating and cooling products.

Thus, it is seen that a thermoelectric device produced by quantum confinement in nanostructures is provided. One skilled in the art will appreciate that the present invention can be practiced by other than the various embodiments and preferred embodiments, which are presented in this description for purposes of illustration and not of limitation, and the present invention is limited only by the claims that follow. It is noted that equivalents for the particular embodiments discussed in this description may practice the invention as well.

What is claimed is:

1. A thermoelectric device, comprising:
a substrate;
a thermoelectric layer; and
a barrier layer;
wherein the barrier layer is formed by partially oxidizing the thermoelectric film to form an oxide layer;
wherein the oxide layer is melted to form the barrier layer.

2. The thermoelectric device of claim 1, wherein:
the substrate forms an electrical insulating and protective barrier on a bottom top surface of the thermoelectric layer; and
the barrier layer forms an electrical insulating and protective barrier on a top surface of the thermoelectric layer.

3. The thermoelectric device of claim 1, wherein the thermoelectric layer comprises a film of thermoelectric material deposited on the substrate.

4. The thermoelectric device of claim 1, wherein one or more electrodes are disposed within the thermoelectric film.

5. The thermoelectric device of claim 1, wherein the substrate comprises a material selected from the group consisting of KCl, KBr and Si.

6. The thermoelectric device of claim 1, wherein the substrate comprises a material selected from the group consisting of quartz glass, quartz crystal, mica and Pyrex glass.

7. The thermoelectric device of claim 1, wherein the thermoelectric layer comprises PbTe.

8. The thermoelectric device of claim 1, wherein the thermoelectric layer comprises a material selected from the group consisting of Bi₂Te₃, SiGe, and ZnSb.

9. The thermoelectric device of claim 1, wherein the oxide layer comprises PbO—TeO₂.

10. The thermoelectric device of claim 1, wherein the thermoelectric layer is vapor deposited on the substrate using a vapor deposition system at a vacuum of about 10⁻² torr to about 10⁻⁹ torr.

11. The thermoelectric device of claim 1, wherein device is subjected to flash-heating to convert the oxide layer from a porous material into a dense glass material.

12. The thermoelectric device of claim 1, wherein the thickness of the thermoelectric layer decreases with increased oxidation time.

13. The thermoelectric device of claim 1, wherein the thickness of the oxide layer increases with increased oxidation time.

14. The thermoelectric device of claim 1, wherein the thermoelectric device comprises multiple thermoelectric layers separated by electrical insulating barrier layers.

15. The thermoelectric device of claim 1, wherein the ZT factor of the thermoelectric device is at least 0.5.

16. The thermoelectric device of claim 1, wherein the ZT factor of the thermoelectric device is at least 1.5.

17. The thermoelectric device of claim 1, wherein the ZT factor of the thermoelectric device is at least 2.5.

18. The thermoelectric device of claim 1, wherein the thermoelectric device is configured to be employed in a refrigerator, a thermoelectric generator or a Peltier device.

19. The thermoelectric device of claim 1, wherein the thermoelectric layer is less than 300 nm in thickness.

20. The thermoelectric device of claim 1, wherein the thermoelectric layer is less than 200 nm in thickness.

21. The thermoelectric device of claim 1, wherein the thermoelectric layer is less than 100 nm in thickness.

22. The thermoelectric device of claim 1, wherein the thermoelectric film thickness is such that the ZT factor is enhanced through the effects of quantum confinement effects such that the ZT factor is higher than that of corresponding bulk material.

23. A thermoelectric device, comprising:
a substrate;
a thermoelectric film comprising PbTe; and
a barrier layer comprising PbO—TeO₂.

24. A thermoelectric device, comprising:
a substrate; and
alternating layers of thermoelectric material and barrier material;
wherein the thermoelectric material comprises PbTe.
